(19) United States
(12) Patent Application Publication
(10) Pub. No.: US 2011/0261854 A1
(43) Pub. Date: Oct. 27, 2011

(54) SEMICONDUCTOR LASER AND MANUFACTURING METHOD THEREOF

(75) Inventor: Chiaki SASAOKA, Kanagawa (JP)

(73) Assignee: RENESAS ELECTRONICS CORPORATION, Kanagawa (JP)

(21) Appl. No.: 13/090,324

(22) Filed: Apr. 20, 2011

(30) Foreign Application Priority Data
Apr. 22, 2010 (JP) 2010-098650

(51) Int. Cl. H01S 5/323; H01L 21/20

(52) U.S. Cl. 372/45.011; 372/45.01; 438/29; 257/E21.09

(57) ABSTRACT

A semiconductor laser includes a semiconductor substrate and a resonator formed over the semiconductor substrate and containing a nitride semiconductor layer. A strain exerting on a region near the facet of the resonator is smaller than a strain exerting on the region between the regions near the facet.

### CROSS-REFERENCE TO RELATED APPLICATION

The disclosure of Japanese Patent Application No. 2010-98650 filed on Apr. 22, 2010 including the specification, drawings and abstract is incorporated herein by reference in its entirety.

### BACKGROUND

The present invention relates to a semiconductor laser and a manufacturing method thereof and for example to a semiconductor laser having a nitride semiconductor layer and a manufacturing method thereof.

Group III element-nitride semiconductors typically represented by gallium nitride (GaN) have attracted attention as materials for light emitting diodes (LEDs) or laser diodes (LDs) since they can emit blue-violet color at high efficiency. Among them, 405 nm band LDs have been expected as light sources for large capacity optical disk devices since they can further restrict a beam than the existent 650 nm band LDs. In recent years, a demand for blue-violet regeneration system LDs has been increased for reproduction of dynamic images at high quality along with popularization of wide screen television sets.

Main degradation factors of blue-violet LDs using GaN include a progressive degradation in which an active layer is degraded due to current supply in the same manner as in GaAs and InP type lasers, and catastrophic optical degradation (COD) fracture in which the facet is accidentally degraded. Particularly, since the COD fracture causing accidental degradation is difficult to be detected by an operation test after manufacture of devices, it is important to design LDs so as not to cause the COD fracture. The background arts for suppressing the COD fracture are described, for example, in Japanese Patent Application Publication Nos. 2000-133875, Hei-08 (1996)-330669, 2002-57406, and 2001-135889.

The semiconductor laser device described in Japanese Patent Application Publication No. 2000-133875 includes a semiconductor substrate, an active layer formed on the semiconductor substrate, and a pair of clad layers sandwiching the acting layer therebetween, in which natural super-lattice in the vicinity of a facet is disordered without heating treatment by merely forming a film containing ZnO to at least one of facets of a resonator of a semiconductor laser after manufacturing a laser structure.

A semiconductor laser described in Japanese Patent Application Publication No. 08 (1996)-330669 includes at least an active layer and first and second clad layers having a band gap larger than that of the active layer that sandwich the active layer therebetween, in which a stripe like excitation region extending in the longitudinal direction of a resonator is disposed to such a length as not reaching a resonator facet, at least one heterobuffer layer is disposed between the first clad layer and a cap layer having a band gap smaller than the first clad layer and formed on the first clad layer in the excitation region, the heterobuffer layer having a band gap intermediate of both of them, and at least one heterobuffer layer is not disposed near the resonator facet sandwiching the excitation region in the longitudinal direction of the resonator, thereby decreasing the amount of a current injected to the vicinity of the resonator facet.

In a facet non-injection type semiconductor laser described in Japanese Patent Application Publication No. 2002-57406, a double heterostructure including an active layer having upper and lower clad layers and a cap layer are stacked above a semiconductor substrate, a clad layer portion disposed in the upper portion of the active layer is formed in a mesa stripe shape to constitute a ridged waveguide, and the mesa height of the clad layer forming the ridged waveguide is made lower than the mesa height of the clad layer forming the ridged waveguide inside the resonator as a current injection portion at the facet of the ridged waveguide and the non-current injection portion disposed in the vicinity thereof, a structure of inhibiting current injection is disposed above the portion of the clad layer where the mesa height is lower, and the width of the mesa bottom in the clad layer region of lower mesa height in the non-current injection portion disposed at the facet and the vicinity thereof is equal with the mesa bottom width in the clad layer region constituting the ridged waveguide inside the resonator as the current injection portion.

In the BH type stripe waveguide semiconductor laser described in Japanese Patent Application Publication No. 2001-135889, a BH type stripe waveguide has an active layer or an optical guide layer attached to the active layer, as well as a clad layer formed of a first semiconductor material having a refractive index smaller than that of the active layer or the active layer and optical guide layer formed above and below thereof, at least one facet functions as a mirror surface forming an optical resonator, a window structure formed by using a semiconductor material formed by embedding growing at the facet that functions as a mirror surface is formed, the window structure has a first semiconductor material layer identical with the clad layer in the stripe waveguide, a second semiconductor material layer having a larger band gap than the oscillation laser light energy of the semiconductor laser is disposed instead of the active layer and the optical guide layer at least a width identical with the active layer in a region extending from the end of the active layer to the mirror surfaces between the first semiconductor material layers disposed above and below thereof.

### SUMMARY

The following analysis is given in accordance with the present invention.

It is generally considered that a COD fracture is caused by the following mechanism. The temperature at a facet is increased to melt a semiconductor and cause a COD fracture by way of the process: (a) a laser light is absorbed in the active layer near the facet to increase the temperature of the active layer, (b) the band gap is reduced by the increase of the temperature to further increase absorption, and (c) the temperature of the active layer is further increased.

Then, for suppressing the COD fracture, (1) it is considered to be effective to form a window structure in which the active layer band gap is increased only in the vicinity of the facet. By the provision of the window structure, laser light absorption at the facet is decreased. As a result, increase of the temperature at the facet is suppressed and the COD fracture can be suppressed. Further, (2) it is also considered effective to form a non-current injection region where current does not flow to the active layer near the facet. By the provision of the non-Current injection region at the facet, current is suppressed from flowing in the vicinity of the facet. As a result, increase of the temperature at the facet due to laser light absorption or the like can be suppressed to suppress the COD fracture.

A method of increasing the band gap near the facet includes a method of disordering a quantum well active layer near the facet as in the technique, for example, of Japanese Patent Application Publication No. 2000-133875. For example, this is performed by diffusing impurities such as Zn or vacant holes from the epitaxial surface only to the vicinity of the facet, and diffusing constituent elements of the well layer and a barrier layer to each other. The band gap is increased in the region causing inter-diffusion since the quantum well is disordered to form mixed crystals. The method utilizes that inter-diffusion of the constituent elements tends to occur in usual III-V group semiconductors such as GaAs and InP. However, since bonding between the constituent elements is intense in the nitride semiconductor, such inter-diffusion is difficult to be generated. Accordingly, the window structure cannot be formed substantially by disordering and the method is not applicable to the nitride semiconductor laser.

On the other hand, when the non-current injection region is formed near the facet as in the techniques, for example, according to Japanese Patent Application Publication Nos. Hei08 (1996)-330669, 2002-57406, and 2001-135889, photolithography is utilized. In the non-current injection region, no inverted population is formed and the absorption loss is increased. Accordingly, in order to minimize the lowering of the laser oscillation efficiency, it is necessary to precisely control the width of the non-current injection region by photolithography within such a range that the absorption loss gives no undesired effect. However, since the nitride semiconductor over the semiconductor substrate has a difference in the lattice constant and the thermal expansion coefficient with respect to the substrate, warp is generated to the wafer. When the warp is generated, the accuracy and the reproducibility of photolithography are lowered and it is extremely difficult to precisely control the width of the non-current injection region within the plane of the wafer. The effect of the warp becomes conspicuous particularly in a case of a large diameter wafer.

According to a first aspect of the invention, there is provided a semiconductor laser including a semiconductor substrate, and a resonator formed on the semiconductor substrate and containing a nitride semiconductor layer. A strain that exerts on a region near the resonator facet is smaller than the strain that exerts on a region between the regions near the facet.

According to a second aspect of the invention, there is provided a semiconductor laser having a semiconductor substrate, and a resonator formed on the semiconductor substrate and containing a nitride semiconductor layer. The lower end at the facet that conducts laser oscillation in the resonator is not in contact with the semiconductor substrate.

According to a third aspect of the invention, there is provided a method of manufacturing a semiconductor laser including forming a nitride semiconductor layer as a precursor of a resonator over a semiconductor substrate, forming a resonator facet that conducts laser oscillation to the nitride semiconductor layer, and removing a portion of the semiconductor substrate below the facet.

The invention has at least one of the following effects.

In the invention, a window structure is formed by utilizing that a band gap is reduced when the nitridate semiconductor layer undergoes strain. That is, the band gap near the facet is increased more than the band gap in other regions by keeping the lower end of the resonator facet from contact with the semiconductor substrate. The linear expansion coefficient is different between the semiconductor substrate and the nitride semiconductor layer. For example, when the semiconductor substrate comprises silicon and the nitride semiconductor layer comprises GaN, since the linear expansion coefficient of GaN is 5.6×10⁻⁶/K⁻¹ while the linear expansion coefficient of Si is 4.2×10⁻/K⁻¹, the nitride semiconductor layer in a region in contact with the semiconductor substrate undergoes a tensile strain. On the other hand, a strain that exerts on the nitride semiconductor layer in a region not in contact with the semiconductor substrate is greatly decreased. Therefore, the bang gap of the nitride semiconductor layer in the region not in contact with the semiconductor substrate is increased more compared with the nitride semiconductor layer in the region in contact with the semiconductor substrate, and a window structure can be formed. With the configuration, absorption of a laser light near the facet not in contact with the semiconductor substrate can be controlled and the COD fracture can be suppressed.

In the invention, a window structure and a non-current injection structure can be obtained simultaneously by fabricating the semiconductor substrate. That is, photolithographic steps can be saved greatly. This can improve the reliability, the reproducibility, and the yield of the semiconductor laser. This is particularly advantageous in a case of using a semiconductor substrate of a large diameter.

### BRIEF DESCRIPTION OF THE DRAWINGS

FIG. 1 is a schematic plan view in the direction of a resonator facet of a semiconductor laser according to a first embodiment of the invention;

FIG. 2 is a schematic step view in perpendicular to both facets of the semiconductor laser according to the first embodiment;

FIGS. 3A to 3C are schematic step views for explaining a method of manufacturing a semiconductor laser in Example 1, in which FIG. 3A shows a step of forming a resonator, FIG. 3B shows a step succeeding to the step shown in FIG. 3A, and FIG. 3C shows a step succeeding to the step shown in 3B;

FIGS. 4D to 4F are schematic step views for explaining a method of manufacturing a semiconductor laser in Example 1, which FIG. 4D shows a step of forming a first electrode, FIG. 4E shows a step succeeding to the step shown in FIG. 4D, and FIG. 4F shows a step succeeding to the step shown in FIG. 4E;

FIGS. 5G to 5I are schematic step views for explaining a method of manufacturing a semiconductor laser in Example 1, in which FIG. 5G shows a step of forming a trench opening in a nitride semiconductor layer, FIG. 5H shows a step succeeding to the step shown in FIG. 5G, and FIG. 5I shows a step succeeding to the step shown in FIG. 5H; and

FIGS. 6J to 6L are schematic step views for explaining a method of manufacturing a semiconductor laser in Example 1, in which FIG. 6J shows a step for completing a laser device, FIG. 6K shows a step succeeding to the step shown in FIG. 6J, and FIG. 6L shows a step succeeding to the step shown in FIG. 6K.

### DETAILED DESCRIPTION

In a preferred embodiment, a semiconductor substrate has a recessed region below the resonator facet such that the semiconductor substrate is not in contact with the resonator.

In a preferred embodiment, the recessed region corresponds to the positions for a window region and a non-current injection region of the resonator.

In the preferred embodiment, the resonator has a lower clad layer and an active layer formed above the lower clad layer. The length from the facet of a region not in contact with the semiconductor substrate at the lower surface of the resonator is not smaller than the thickness of the lower clad layer.

In a preferred embodiment, the length from the facet of a region not in contact with the semiconductor substrate at the lower surface of the resonator is less than 20 μm.

In a preferred embodiment, the semiconductor laser further has a first electrode electrically coupled with the resonator and a second electrode electrically coupled with the semiconductor substrate.

In a preferred embodiment, a portion of the semiconductor substrate is removed by utilizing an opening in the nitride semiconductor layer formed upon forming the facet.

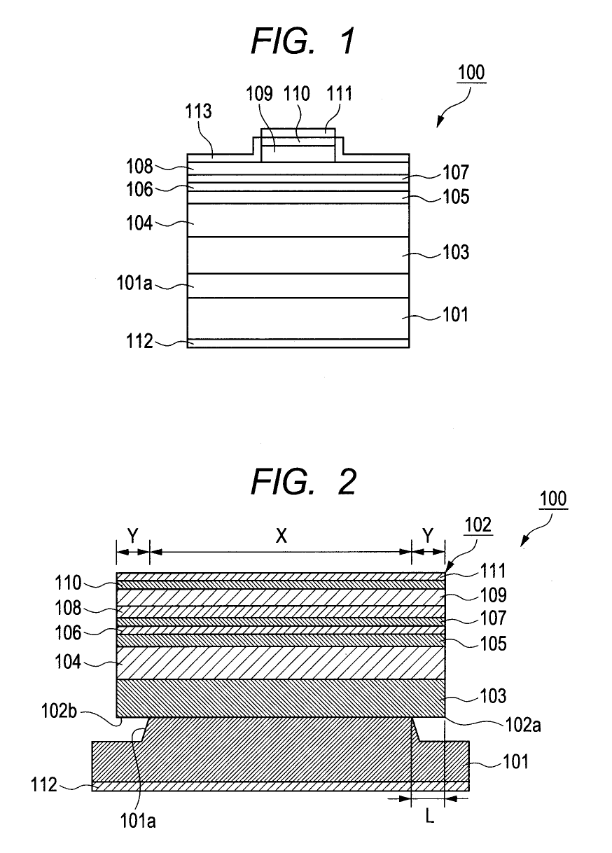

A semiconductor laser according to a first embodiment of the invention is to be described. FIG. 1 is a schematic plan view in the direction of a resonator facet of a semiconductor laser according to the first embodiment of the invention. FIG. 2 is a schematic cross sectional view perpendicular to (along a ridge extending direction) to both facets of a semiconductor laser according to the first embodiment of the invention.

A semiconductor laser 100 according to the first embodiment of the invention includes a semiconductor substrate 101 and a resonator 102 formed above the semiconductor substrate 101 and including a nitride semiconductor layer. A lower end 102a at the resonator facet 102 that conducts laser oscillation is not in contact with the semiconductor substrate 101. The semiconductor substrate 101 has a recessed region 101a below the resonator facet 102 so as not to be in contact with the lower end 102a. The recessed region 101a is preferably formed for the entire width of the resonator 102. That is, it is preferred that the semiconductor substrate 101 does not support the region near the resonator facet 102 by the provision of the recessed region 101a. The recessed region 101a corresponds to a window region and a non-current injection region.

In the semiconductor laser 100 according to the first embodiment of the invention, the resonator 102 includes, for example, a buffer layer 103, a lower clad layer 104, a lower optical confinement layer 105, an active layer (multiple quantum well layer) 106, a cap layer 107, an upper optical confinement layer 108, an upper clad layer 109, and a contact layer 110. The upper clad layer 109 and the contact layer 110 are formed in a ridged shape. A first electrode 111 is electrically coupled over the contact layer 110 (preferably for the entire upper surface), and a second electrode 112 is electrically coupled below the semiconductor substrate 101 (preferably for the entire lower surface or in a region corresponding to the first electrode 111). In this case, the semiconductor substrate 101 has electroconductivity and current is supplied by way of the first electrode 111 and the second electrode 112 to the semiconductor laser 100. A protective layer 113 is formed to the upper surface and the lateral sides of the ridge of the upper optical confinement layer 108.

In the lower surface 102b of the resonator, the length not in contact with the semiconductor substrate 101 (length L of the non-contact region Y), that is, the depth of the recessed region 101a from the resonator facet is preferably set in view of the width of the window region and the width of the non-current injection facet. The length L of the non-contact region Y is preferably not less than the thickness of the lower clad layer 104 in view of the width of the non-current injection facet. If the length L of the non-contact region Y is shorter than the thickness of the lower clad layer 104, the non-injection effect is lowered due to the lateral diffusion of the current in the lower clad layer 104. In view of the width of the window region, the length L of the non-contact region Y is preferably less than 20 μm and, more preferably, 15 μm or less. If the length L of the non-contact region Y is longer than 20 μm, the absorption loss in the window region is excessively large to result in lowering of the oscillation efficiency. Further, the resonator is not supported at the non-contact region Y by the semiconductor substrate 101. Accordingly, When the length L of the non-contact region Y is longer than 20 μm, the vicinity of the resonator facet tends to be fractured when external stress exerts.

When the electrodes 111 and 112 are formed above and below the semiconductor laser 100, a current flows from the second electrode 112 by way of the semiconductor substrate 101 to the active layer 106 during current supply. However, since the both facets of the resonator 102 are not in contact with the semiconductor substrate 101, the current does not flow in the non-contact region Y near the both facets. Thus, according to the invention, the window structure and the non-current injection structure can be obtained simultaneously.

Further, the tensile strain that exerts on the non-contact region Y of the resonator 102 (particularly, active layer 106) above the region not in contact with the semiconductor substrate 101 is smaller than the tensile strain that exerts on the contact region X of the resonator 102 (particularly, active layer 106) above the region in contact with the semiconductor substrate 101. Accordingly, the band gap of the non-contact region Y is larger than the band gap in the contact region X and absorption of the laser light in the non-contact region Y is suppressed. This provides the window structure.

An example of the semiconductor laser 100 according to the first embodiment is shown below. The semiconductor laser 100 can be configured, for example, by a structure of stacking an n-type Si substrate as a semiconductor substrate 101, an AlN (5 nm)/GaN (10 nm) super lattice buffer layer (Si concentration: 4×10¹⁸ cm⁻³, thickness: 2 μm) as a buffer layer 103, an Si doped n-type Al_{0.1}Ga_{0.9}N clad layer (Si concentration: 4×10¹⁷ cm⁻³, thickness: 2 μm) as a lower clad layer 104, an Si doped n-type GaN (Si concentration: 4×10¹⁷ cm⁻³, thickness: 0.1 μm) optical confinement layer as a lower optical confinement layer 105, a 3-period multiple quantum well (MQW) active layer having an In_{0.15}Ga_{0.85}N (thickness: 3 nm) well layer and an Si doped In_{0.01}Ga_{0.99}N barrier layer (Si concentration: 1×10¹⁸ cm⁻³, thickness: 4 nm) as an active layer 106, an Mg doped p-type Al_{0.2}Ga_{0.13}N cap layer (Mg concentration: 2×10¹⁹ cm⁻³, thickness: 10 nm) as a cap layer 107, an Mg doped p-type GaN optical confinement layer (Mg concentration: 1×10¹⁹ cm⁻³, thickness: 0.1 μm) as the upper optical confinement layer 108, a p-type Al_{0.1}Ga_{0.9}N clad layer (thickness: 0.8 μm) as the upper clad layer 109, and an Mg doped p-type GaN contact layer (Mg concentration: 1×10²⁰ cm⁻³, thickness: 0.02 μm) as the contact layer 110. The first electrode 111 can be formed, for example, as a p-type electrode and a second electrode can be formed, for example, as an n-type electrode. Further, the protective layer 113 can be formed, for example, of a silicon oxide film.

The plane direction of the Si substrate is preferably a plane direction such as (111), (100), (110), (211), or (311) with a view point of the crystal growing of the nitride semiconductor. The effect of suppressing the COD fracture in the invention does not qualitatively depend on the direction of plane of the Si substrate. This is because the window structure is formed by utilizing that a tensile stress exerts on the nitride semiconductor active layer formed over the Si substrate in the invention.

Then, a method of manufacturing a semiconductor laser according to the invention is to be described. At first, a nitride semiconductor layer as a precursor of the resonator is formed over a semiconductor substrate. Then, the nitride semiconductor layer is etched to form a resonator facet. Then, the region of the semiconductor substrate below the resonator facet is partially removed to form a recessed region by utilizing an opening in the nitride semiconductor layer manufactured upon forming the resonator facet. As a method of partially removing the semiconductor substrate, etching can be utilized. The recessed region may be formed also in a step identical with that for forming the resonator facet. This can save the number of steps in the process of manufacturing the semiconductor laser. The manufacturing method is to be described in details in the following example.

### Example

### Manufacture of a Semiconductor Laser

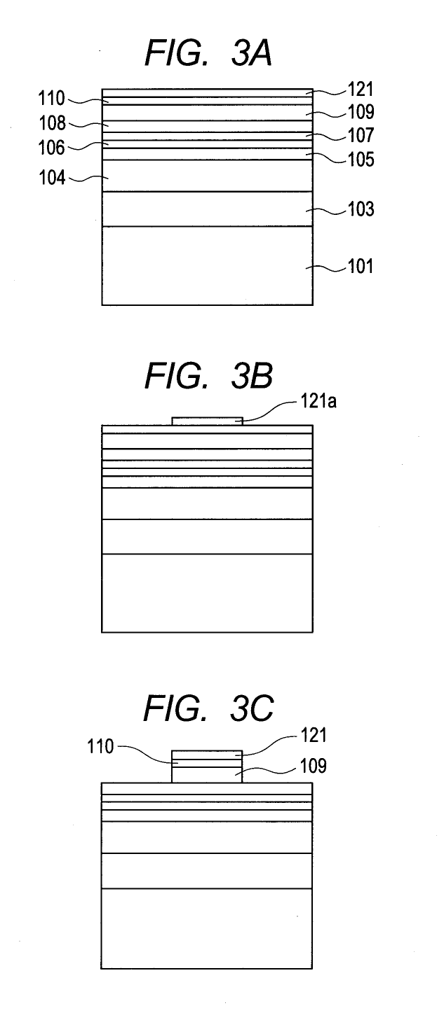

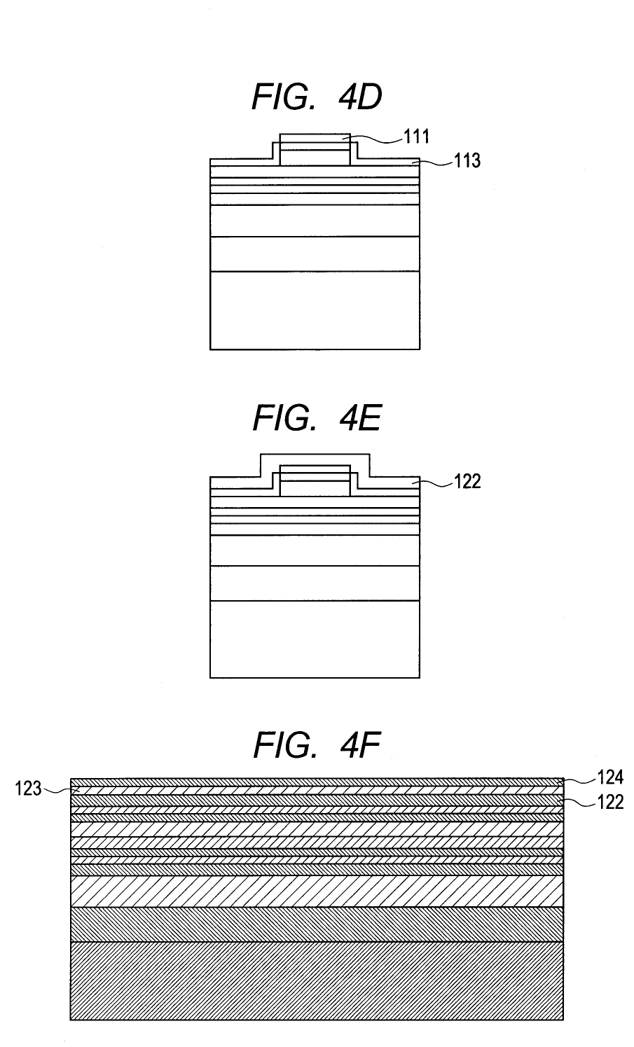

The semiconductor laser shown as the example described above was manufactured. FIG. 3A to FIG. 6L are schematic step charts for explaining the method of manufacturing the semiconductor laser. FIG. 3A to FIG. 4E are schematic plan views in the direction of the resonator facet and FIG. 4F to FIG. 6L are schematic cross sectional views along a plane perpendicular to the resonator facet.

As the semiconductor substrate 101, an n-type silicon substrate having a plane direction (111) was used. For the manufacture of a device structure, a metal organic vapor phase epitaxy (MOVPE) apparatus at 300 hPa was used. A gas mixture of hydrogen and nitrogen was used as a carrier gas and trimethyl gallium (TMG), trimethyl aluminum (TMA), and trimethyl indium (TMI) were used as Ga, Al and In sources respectively and silane (SiH₄) was used as then-type dopant and biscyclopentadiethyl magnesium (Cp₂Mg) was used for the p-type dopant.

After loading the n-type silicon substrate 101 in the MOVPE apparatus, the temperature of the silicon substrate was increased in an N₂ carrier gas, a group 13 starting material, a dopant, and NH₃ were supplied at the instance reaching the growing temperature, and each of the precursor layers, i.e., for the buffer layer 103 to the contact layer 110 as the example described above was deposited successively over the n-type silicon substrate to manufacture a precursor for the resonator (FIG. 3A). GaN was grown under the condition at a substrate temperature of 1080° C., a TMG supply amount of 58 μmol/min, and an NH₃ supply amount of 0.36 mol/min. AlGaN was grown under the condition at a substrate temperature of 1080° C., a TMA supply amount of 36 μmol/min, a TMG supply amount of 58 μmol/min, and an NH₃ supply amount of 0.36 mol/min. InGaN MQW was grown under the conditions at a substrate temperature of 800° C., a TMG supply amount of 8 mol/min, and an NH₃ supply amount of 0.36 mol/min. The TMI supply amount was adjusted to 48 mol/min upon forming a well layer and adjusted to 3 mol/min upon forming a barrier layer.

An SiO₂ film 121 was formed over the precursor of the resonator (FIG. 3A), and the SiO₂ film 121 was formed into an SiO₂ stripe 121a of 1.3 μm width by photolithography (FIG. 3B). Precursor layers for the upper clad layer 109 and the contact layer 110 were partially removed by dry etching using the SiO₂ stripe 121a as a mask to form a ridged structure (FIG. 3C).

Then, the SiO₂ stripe 121a was removed and an SiO₂ film was deposited again as a protective film 113 over the entire surface of the wafer. Then, a resist was coated thickly and the ridged top was formed by etching back in an oxygen plasma. After removing the ridge top SiO₂ film by a buffer hydrofluoric acid, Pd/Pt were deposited by electron beams and a first electrode 111 was formed by lift-off. Then, the resist was removed (FIG. 4D).

Then, a rapid thermal annealing (RTA) was applied in a nitrogen atmosphere at 600° C. for 30 sec to form a p-ohmic electrode. Then, Ti for 50 nm, Pt for 100 nm and Au for 2 μm were deposited by sputtering to form a cover electrode 122 (FIG. 4E).

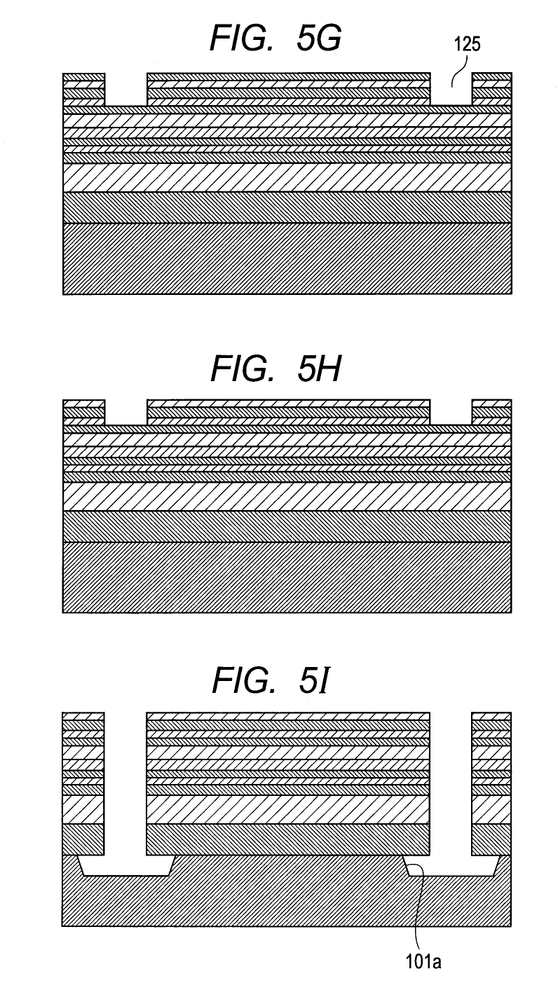

Then, an SiO₂ film 123 was formed by sputtering over the entire surface of the wafer, and a resist 124 was coated over the SiO₂ film 123. Then, a trench opening 125 for forming the resonator facet was formed to the resist 124 in perpendicular to the stripe. Then, the SiO₂ film 123 exposed to the trench opening 125 was removed by dry etching. In this case, the trench width of the trench opening 125 was defined as 5 μm and the distance between adjacent trench openings 125 was set such that the resonator length was 400 μm. Then, the cover electrode 122 and the first electrode 111 exposed in the trench opening 125 were removed by milling (FIG. 5G). Successively, the resist 124 was removed (FIG. 5H).

Then, the nitride semiconductor layers 103 to 110 and a portion of the Si substrate 101 were etched by chlorine type dry etching using the SiO₂ film 123 as a mask to form the laser facet of the resonator. Then, the laser facet and the exposed Si substrate 101 were wet etched by using a 25% aqueous solution of TMAH (tetramethyl ammonium hydroxide) kept at 80° C. A portion of the Si substrate in the region below the laser facet was removed by etching using TMAH to form a recessed region 101a, and a damaged layer at the laser facet introduced by chlorine type dry etching was removed (FIG. 5I).

After wet etching with TMAH, a portion of the wafer was sampled and emission wavelength was measured for the active layer 106 by microscopic electroluminescence beam diameter measurement. As a result, while the emission wavelength of the active layer on the region in contact with the Si substrate 101 (contact region X referred to in FIG. 2) was 403 nm, the emission wavelength in the active layer above the recessed region 101a (non-contact region Y referred to in FIG. 2) was 406 nm. Thus, it was confirmed that the band gap is increased to form the window structure in the active layer 106 near the facet by the formation of the recessed region 101a.

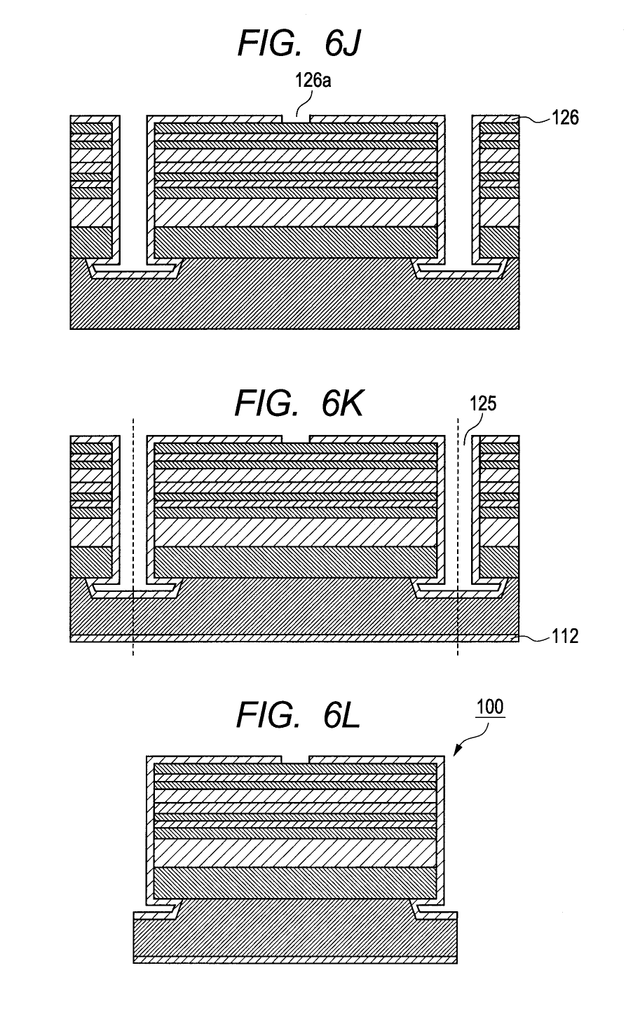

Then, an SiO₂ film 126 was deposited to a thickness of 0.5 μm over the entire surface of the wafer by CVD to form a protective film for the resonator facet. Then, an opening 126a for a bonding pad electrode was formed in the SiO₂ film 126 by photolithography to expose the cover electrode 122 (FIG. 6J).

Then, the rear face of the Si substrate 101 was polished to reduce the thickness of the wafer to 100 μm and then 5 nm Ti, 20 nm Al, 10 nm Ti, and 500 nm Au were vapor deposited in this order to the rear face of the Si substrate to form a second electrode 112 (FIG. 6K).

Then, the Si substrate 101 was separated into a bar shape by the trench openings 125, and each of the bars was divided into individual devices to manufacture a semiconductor laser 100 (FIG. 6L). Finally, the semiconductor laser 100 was sealed in a CAN package to obtain a laser package.

### [Measurement for Threshold Current and Slope Efficiency]

Semiconductor lasers having different length L of non-contact region in which the lower surface of the resonator was not in contact with the semiconductor substrate were manufactured, and the slope efficiency was measured for each of the semiconductor lasers. The length L for the non-contact region was adjusted by the time of the wet etching with TMAH. Table 1 shows the average value for the oscillation threshold current Ith and the average value for the slope efficiency for each of the semiconductor lasers. Each of the average values is an average for measured average values by the number of 20.

TABLE 1

| | Length of | Oscillation | Slope |
|---|---|---|---|
| | non-contact | threshold | efficiency |
| | region (μm) | current (mA) | (W/A) |
| Example 1 | 2 | 31 | 1.2 |
| Example 2 | 5 | 34 | 1.3 |
| Example 3 | 10 | 33 | 1.1 |
| Example 4 | 15 | 32 | 1.1 |
| Comparative | 20 | 42 | 0.7 |
| Example 1 | | | |

When the length L of the non-contact region was 2 μm to 15 μm, the oscillation threshold current was 31 mA to 34 mA and the slope efficiency was 1.1 W/A to 1.3 W/A, and they were constant. However, when the length L of the non-contact region was increased to 20 μm, the oscillation threshold current increased to as high as 42 mA and the slope efficiency was decreased to as low as 0.7 W/A. It is considered that since the internal loss was increased due to the increase of the width of the window region and the width of the non-current injection region, an oscillation threshold current was increased and the slope efficiency was lowered.

Further, for semiconductor lasers having the length L of the non-contact region of 20 μm, it was observed that about 10% of the entire devices did not conduct laser oscillation. When the appearance of the device failed in oscillation was observed by a scanning type electron microscope, it was confirmed that the nitride semiconductor layer was deformed or fractured near the facet. It was estimated that since the resonator was not supported in the non-contact region by the substrate, fracture tends to be caused when an external stress was applied during the process, and that since the trend became conspicuous when the non-contact region was long, device was failed at the 20 μm length.

### [Electrostatic Discharge Test and Automatic Output Control Test]

For semiconductor lasers in which the lower surface of the resonator was not in contact with the semiconductor substrate and the length L of the non-contact region was different, an electrostatic discharge (ESD) test and an automatic power control (APC) test were performed to confirm the durability of each of the semiconductor lasers.

The ESD test was practiced based on a machine model. In the semiconductor laser having the length L of the non-contact region of 0 μm, the ESD level was at about 30 V. On the contrary, in the semiconductor laser having the length of the non-contact region of 2 μm to 15 μm, the ESD level was stable and a value of about 90 V was obtained. When the semiconductor laser after fracture was observed, abnormality was observed for the emission facet in any of the devices and it was found that COD fracture was caused by instantaneous application of voltage. For the semiconductor laser having the length of the non-contact region of 0 μm, it is considered that since the window structure and the non-current injection structure were not formed, COD fracture was caused at lower ESD voltage.

The APC test for confirming the long time reliability was practiced under the condition at 30 mW, CW at an ambient temperature of 80° C. for 1,000 hours. In semiconductor lasers having the length for the non-contact region of 2 μm to 15 μm, stable driving was confirmed for 1,000 hours. On the other hand, in semiconductor lasers having the length for the non-contact region of 0 μm, accidental degradation was generated for about one-half of the devices. By the observation for the degraded devices, COD fracture at the emission facet was confirmed in each of the devices.

In view of the above, it was found that a semiconductor laser of high reliability suppressed from the COD fracture was obtained by forming a non-contact region (recessed region) longer than 0 μm and shorter than 20 μm.

While the semiconductor laser and a manufacturing method thereof of the present invention have been described with reference to the embodiments described above, it will be apparent that the invention is not restricted to the embodiments described above but various modifications, changes, and improvements are included in the embodiments described above within the range of the invention and based on the fundamental technical idea of the invention. Further, various combination, substitutions, or selections are possible for various disclosed elements within the scope of the claim for patent of the present invention.

Further subjects, purposes, and the states of development of the present invention will be apparent from the entire disclosure of the invention including those in the scope of the claim for patent.

What is claimed is:

1. A semiconductor laser comprising:
a semiconductor substrate; and
a resonator containing a nitride semiconductor layer, the resonator being formed over the semiconductor substrate,
wherein a strain exerting on a region near the resonator facet is smaller than a strain exerting on a region between the regions near the facet.

2. A semiconductor laser comprising:
a semiconductor substrate; and
a resonator containing a nitride semiconductor layer, the resonator being formed over the semiconductor substrate,
wherein the lower end of the resonator facet that conducts laser oscillation is not in contact with the semiconductor substrate.

3. The semiconductor laser according to claim 1, wherein the semiconductor substrate has a recessed region below the resonator facet such that the semiconductor substrate is not in contact with the resonator.

4. The semiconductor laser according to claim 3, wherein the recessed region corresponds to the positions for a window region and a non-current injection region of the resonator.

5. The semiconductor laser according to claim 2,
wherein the resonator has a lower clad layer and an active layer formed above the lower clad layer, and
wherein the length from the facet of the region not in contact with the semiconductor substrate in the lower surface of the resonator is not less than the thickness of the lower clad layer.

6. The semiconductor laser according to claim 2, wherein the length from the facet of the region not in contact with the semiconductor substrate in the lower surface of the resonator is less than 20 μm.

7. The semiconductor laser according to claim 1, further comprising:
a first electrode electrically coupled with the resonator and a second electrode electrically coupled with the semiconductor substrate.

8. A method of manufacturing a semiconductor laser, comprising:
forming a nitride semiconductor layer as a precursor of a resonator over a semiconductor substrate;
forming a facet of the resonator that conducts laser oscillation to the nitride semiconductor layer; and
removing a portion of the semiconductor substrate below the facet.

9. The method of manufacturing a semiconductor laser according to claim 8, wherein a portion of the semiconductor substrate is removed by utilizing an opening in the nitride semiconductor layer formed upon forming the facet.
